(19) United States
(12) Patent Application Publication
(10) Pub. No.: US 2022/0199406 A1
(43) Pub. Date: Jun. 23, 2022

(54) VAPOR DEPOSITION OF CARBON-DOPED METAL OXIDES FOR USE AS PHOTORESISTS

(71) Applicant: Applied Materials, Inc., Santa Clara, CA (US)

(72) Inventors: Lakmal Charidu Kalutarage, San Jose, CA (US); Mark Joseph Saly, Milpitas, CA (US); Ruiying Hao, San Jose, CA (US); Wayne French, San Jose, CA (US); Kelvin Chan, San Ramon, CA (US)

(21) Appl. No.: 17/534,287

(22) Filed: Nov. 23, 2021

Related U.S. Application Data
(60) Provisional application No. 63/126,977, filed on Dec. 17, 2020.

(51) Int. Cl. H01L 21/033; H01J 37/32; G03F 7/004; G03F 7/16

(52) U.S. Cl. CPC H01L 21/0337; H01J 37/32449; H01J 2237/332; G03F 7/167; H01L 21/0332; G03F 7/0044

(57) ABSTRACT

Embodiments disclosed herein include a method of forming a metal-oxo photoresist on a substrate. In an embodiment, the method comprises repeating a deposition cycle, where each iteration of the deposition cycle comprises: a) flowing a metal precursor into a chamber comprising the substrate; and b) flowing an oxidant into the chamber, where the oxidant and the metal precursor react to form the metal-oxo photoresist.

### CROSS-REFERENCE TO RELATED APPLICATIONS

This application claims benefit of U.S. Provisional Application No. 63/126,977, filed on Dec. 17, 2020, the entire contents of which are hereby incorporated by reference herein.

### BACKGROUND

### 1) Field

Embodiments of the present disclosure pertain to the field of semiconductor processing and, in particular, to methods of depositing a photoresist layer onto a substrate using vapor phase processes.

### 2) Description of Related Art

Lithography has been used in the semiconductor industry for decades for creating 2D and 3D patterns in microelectronic devices. The lithography process involves spin-on deposition of a film (photoresist), irradiation of the film with a selected pattern by an energy source (exposure), and removal (etch) of exposed (positive tone) or non-exposed (negative tone) region of the film by dissolving in a solvent. A bake will be carried out to drive off remaining solvent.

The photoresist should be a radiation sensitive material and upon irradiation a chemical transformation occurs in the exposed part of the film which enables a change in solubility between exposed and non-exposed regions. Using this solubility change, either exposed or non-exposed regions of the photoresist is removed (etched). Now the photoresist is developed and the pattern can be transferred to the underlying thin film or substrate by etching. After the pattern is transferred, the residual photoresist is removed and repeating this process many times can give 2D and 3D structures to be used in microelectronic devices.

Several properties are important in lithography processes. Such important properties include sensitivity, resolution, lower line-edge roughness (LER), etch resistance, and ability to form thinner layers. When the sensitivity is higher, the energy required to change the solubility of the as-deposited film is lower. This enables higher efficiency in the lithographic process. Resolution and LER determine how narrow features can be achieved by the lithographic process. Higher etch resistant materials are required for pattern transferring to form deep structures. Higher etch resistant materials also enable thinner films. Thinner films increase the efficiency of the lithographic process.

### SUMMARY

Embodiments disclosed herein include a method of forming a metal-oxo photoresist on a substrate. In an embodiment, the method comprises repeating a deposition cycle, where each iteration of the deposition cycle comprises: a) flowing a metal precursor into a chamber comprising the substrate; and b) flowing an oxidant into the chamber, where the oxidant and the metal precursor react to form the metal-oxo photoresist.

Additional embodiments include a method of forming a metal-oxo photoresist on a substrate. In an embodiment, the method comprises repeating a deposition cycle, where each iteration of the deposition cycle comprises: a) flowing a metal precursor into a chamber comprising the substrate; and b) flowing an oxidant into the chamber, where the oxidant and the metal precursor react to form the metal-oxo photoresist. In an embodiment, the method further comprises treating the metal-oxo photoresist with a plasma treatment after a first number of iterations of the deposition cycle.

In yet another embodiment, a method of forming a metal oxo photoresist on a substrate is disclosed. In an embodiment, the method comprises repeating a deposition cycle, where each iteration of the deposition cycle comprises: a) flowing a metal precursor into a chamber comprising the substrate, where the metal precursor comprises a general formula of MR_{X}L_{Y}, where X=0-4 and Y=4-X, and where M is a metal, R is a linear alkyl, a branched alkyl, or a cyclic alkyl, and L is a alkyl amino, Cl, Br, CN, CNO, SCN, N₃, or SeCN; b) purging the chamber; c) flowing an oxidant into the chamber, where the oxidant and the metal precursor react to form the metal oxo photoresist, where the oxidant comprises one or more of water, O₂, ethylene glycol, alcohols, peroxides, and acids; and d) purging the chamber.

### BRIEF DESCRIPTION OF THE DRAWINGS

FIG. 1 is a flowchart illustrating a process for depositing a metal oxo photoresist on a substrate using a vacuum deposition process, in accordance with an embodiment.

FIG. 2 is a flowchart illustrating an additional process for depositing a metal oxo photoresist on a substrate with a vacuum deposition process with plasma treatments, in accordance with an embodiment.

FIG. 3 is a plan view schematic of a processing tool that allows for a spatial atomic layer deposition process to be used to deposit a metal oxo photoresist on a substrate, in accordance with an embodiment.

FIG. 4A is a cross-sectional illustration of a substrate with a metal oxo photoresist, in accordance with an embodiment.

FIG. 4B is a cross-sectional illustration of a substrate with a metal oxo photoresist with a first layer and a second layer, in accordance with an embodiment.

FIG. 5 is a cross-sectional illustration of a processing tool that may be used to implement the process in FIG. 1 or FIG. 2, in accordance with an embodiment of the present disclosure.

FIG. 6 illustrates a block diagram of an exemplary computer system, in accordance with an embodiment of the present disclosure.

### DETAILED DESCRIPTION

Methods of depositing a photoresist on a substrate using vapor phase processes are described herein. In the following description, numerous specific details are set forth in order to provide a thorough understanding of embodiments of the present disclosure. It will be apparent to one skilled in the art that embodiments of the present disclosure may be practiced without these specific details. In other instances, well-known aspects, such as integrated circuit fabrication, are not described in detail in order to not unnecessarily obscure embodiments of the present disclosure. Furthermore, it is to be understood that the various embodiments shown in the Figures are illustrative representations and are not necessarily drawn to scale.

To provide context, photoresist systems used in extreme ultraviolet (EUV) lithography suffer from low efficiency. That is, existing photoresist material systems for EUV lithography require high dosages in order to provide the needed solubility switch that allows for developing the photoresist material. Organic-inorganic hybrid materials (e.g., metal oxo materials systems) have been proposed as a material system for EUV lithography due to the increased sensitivity to EUV radiation. Such material systems typically comprise a metal (e.g., Sn, Hf, Zr, etc.), oxygen, and carbon. Metal oxo based organic-inorganic hybrid materials have also been shown to provide lower LER and higher resolution, which are required characteristics for forming narrow features.

Metal oxo material systems are currently disposed over a substrate using a wet process. The metal oxo material system is dissolved in a solvent and distributed over the substrate (e.g., a wafer) using wet chemistry deposition processes, such as a spin coating process. Wet chemistry deposition of the photoresist suffers from several drawbacks. One negative aspect of wet chemistry deposition is that a large amount of wet byproducts are generated. Wet byproducts are not desirable and the semiconductor industry is actively working to reduce wet byproducts wherever possible. Additionally, wet chemistry deposition may result in non-uniformity issues. For example, spin-on deposition may provide a photoresist layer that has a non-uniform thickness or non-uniform distribution of the metal oxo molecules. Additionally, it has been shown that metal oxo photoresist material systems suffer from thickness reduction after exposure, which is troublesome in lithographic processes. Furthermore, in a spin-on process, the percentage of metal in the photoresist is fixed, and cannot be easily tuned.

Accordingly, embodiments of the present disclosure provide a vacuum deposition process for providing a metal oxo photoresist layer. The vacuum deposition process (e.g., an atomic layer deposition (ALD) process) addresses the shortcomings of the wet deposition process described above. Particularly, a vacuum deposition process provides the advantages of: 1) eliminating the generation of wet byproducts; 2) providing a highly uniform photoresist layer; 3) resisting thickness reduction after exposure; and 4) providing a mechanism to tune the percentage of metal in the photoresist.

Embodiments disclosed herein provide various vacuum deposition processes that comprise the reaction of a metal precursor with an oxidant. In a first embodiment, the vacuum deposition process may be an ALD process. The vacuum deposition process may be a thermal process in some embodiments. In other embodiments, the vacuum deposition process may be a plasma enhanced (PE) deposition process (e.g., PE-ALD). The vacuum deposition process may further comprise plasma treatments (e.g., before deposition, after a predetermined number of deposition cycles, and/or after the final deposition cycle).

In addition to providing enhanced uniformity (e.g., thickness uniformity, composition uniformity across the surface, etc.), the use of an ALD process provides significant flexibility in the composition (in the thickness direction) of the metal oxo photoresist. For example, the composition may be modified by altering the precursors during different cycles of the deposition process. Such modifiable metal oxo structures allow for fine tuning the photoresist for different applications. In one such application, a main portion of the metal oxo photoresist is optimized for dose, and a different composition close to the interface with the underlying substrate is tuned for adhesion, sensitivity to EUV photons, sensitivity to develop chemistry, or the like. This improves post lithography profile control, such as scumming, defectivity, and resist collapse/lift off. Additionally, the gradation of the metal oxo photoresist may be optimized for pattern type. For example, pillars need improved adhesion, whereas line/space patterns may need lower adhesion and can be optimized for improvements in dose sensitivity.

In an embodiment, the vacuum deposition process relies on chemical reactions between a metal precursor and an oxidant. The metal precursor and the oxidant are vaporized to a vacuum chamber. The metal precursor reacts with the oxidant to form a photoresist layer comprising a metal oxo on the surface of a substrate. In some embodiments, the metal precursor and the oxidant are provided to the vacuum chamber with alternating pulses. In an ALD or PE-ALD process, a purge of the vacuum chamber may be provided between pulses of the metal precursor and the oxidant.

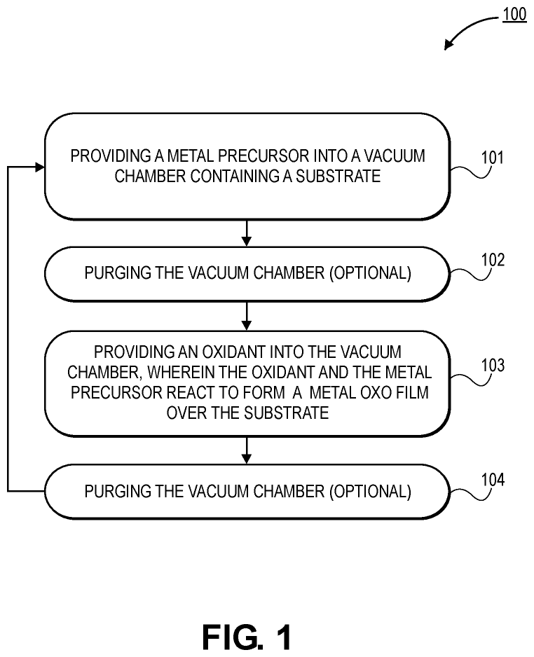

Referring now to FIG. 1, a process 100 for depositing a metal oxo photoresist on a substrate is shown, in accordance with an embodiment. In an embodiment, the metal oxo photoresist is deposited on a substrate, such as, but not limited to, a silicon wafer. It is to be appreciated that the substrate may comprise materials other than silicon.

In an embodiment, process 100 begins with operation 101 which comprises providing a metal precursor into a vacuum chamber containing the substrate. In an embodiment, the metal precursor may have the general formula of MR_{X}L_{Y}, where X=0-4 and Y=4-X. M is a metal, such as one or more of Sn, Hf, Zr, Co, Cr, Mn, Fe, Cu, Ni, Mo, W, Ta, Os, Re, Pd, Pt, Ti, V, In, Sb, Al, As, Ge, Se, Cd, Ag, Pb, Au, Er, Yb, Pr, La, Na, and Mg. In an embodiment, R is an alkyl (e.g., C1-C10). The alkyl may be a linear alkyl, a branched alkyl, or a cyclic alkyl (e.g., tBu, nBu, Sec-butyl, or iPr). R may also be an alkenyl, alkynyl, aryl, or a benzyl. Structures (1) and (2) are pictorial illustrations of examples of a pair of suitable MR structures. In an embodiment, L is a alkyl (C1-C10) amino, such as dimethylamino or methylethylamino. L may also comprise Cl, Br, CN, CNO, SCN, N₃, or SeCN. Structures (3), (4), and (5) are pictorial illustrations of examples of a suitable ML structures. An example of a complete metal precursor (e.g., a tin precursor) is shown in Structure (6). The R component may be modified to alter the exposure sensitivity of the metal oxo film. The reactivity between the metal precursor and the oxidant can be modulated by changing the R and/or L on the metal precursor.

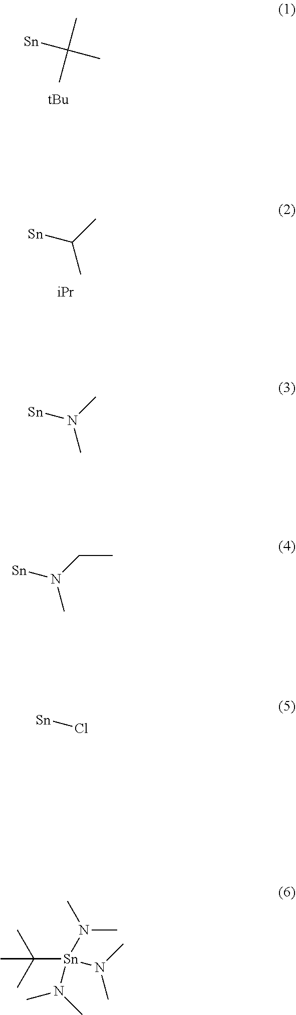

In an embodiment, a single metal precursor species may be flown into the chamber. In other embodiments, two or more different metal precursor species may be flown into the chamber. For example, metal precursors with different metals M may be used in some embodiments. In an embodiment, the metal precursor may be flown into the chamber by itself. In other embodiments, an inert carrier gas may also be flown into the chamber with the metal precursor. The carrier gas may be an inert gas such as, Ar, N₂, or He. In an embodiment, the metal precursor absorbs to the surface of the substrate.

In an embodiment, process 100 may continue with operation 102 which comprises purging the vacuum chamber. The purging operation is optional in some embodiments. That is, in some embodiments, process 100 may continue from operation 101 directly to operation 103. The purge of the chamber may comprise flowing an inert gas such as Ar, N₂, or He into the chamber.

In an embodiment, process 100 may continue with operation 103, which comprises providing an oxidant into the vacuum chamber. The oxidant and the metal precursor react to form a metal oxo film over the substrate. In general, the metal oxo film contains M-O and M-C bonds in the MOC network. Upon exposure (e.g., UV or EUV light), M-C bonds break and the carbon percentage in the film is reduced. This leads to the selective etch during the develop process. In an embodiment, the oxidant may comprise one or more of water, O₂, ethylene glycol, alcohols (e.g., methanol, ethanol, etc.), peroxides (e.g., H₂O₂), and acids (e.g., formic acid, acetic acid, etc.).

In an embodiment, process 100 may continue with operation 104, which comprises purging the vacuum chamber. The purging operation is optional in some embodiments. That is, in some embodiments, process 100 may continue from operation 103 directly to operation 101. The purge of the chamber may comprise flowing an inert gas such as Ar, N₂, or He into the chamber.

As indicated by the arrow from operation 104 to operation 101, the process 100 may be repeated for any number of cycles in order to provide a metal oxo film with a desired thickness. In an embodiment, each iteration of the deposition cycle uses the same processing gasses. In other embodiments, the processing gasses may be changed between cycles. For example, a first deposition cycle may utilize a first metal precursor vapor, and a second deposition cycle may utilize a second metal precursor vapor. Subsequent deposition cycles may continue alternating between the first metal precursor vapor and the second metal precursor vapor in some embodiments. In an embodiment, multiple oxidant vapors may be alternated between cycles in a similar fashion. In yet another embodiment, a first metal precursor and a first oxidant may be used to provide a metal oxo layer with a high adhesion strength, and subsequent deposition cycles may use a second metal precursor and a second oxidant to provide high sensitivities for the metal oxo film.

In an embodiment, each of the processing operations 101-104 may be executed for any duration of time. For example, the processing operations 101-104 may be implemented for a duration between approximately one millisecond and one minute. The durations of each operation 101-104 need not be the same in some embodiments. The durations or each operation 101-104 may also differ between deposition cycles.

In an embodiment, the process 100 is implemented as a thermal process. That is, the process 100 may be implemented without the presence of a plasma. Such a process may be referred to as an ALD process in some embodiments. In an embodiment, a temperature of the substrate may be maintained between approximately −40° C. and approximately 500° C.

In yet another embodiment, a plasma may be ignited during one or more of the processing operations 101-104. In such instances, the presence of the plasma may enhance the chemical reaction used to form the metal oxo photoresist. Such an embodiment may be referred to as a PE-ALD process. In an embodiment, any plasma source may be used to form the plasma. For example, the plasma source may include, but is not limited to, a capacitively coupled plasma (CCP) source, an inductively coupled plasma (ICP) source, a remote plasma source, or a microwave plasma source.

In the illustrated embodiment, the process 100 is shown as starting with operation 101. However, it is to be appreciated that the process 100 may begin with any of the processing operations 101-104. For example, starting with operation 103 may help treat the surface of the substrate in order to improve the adhesion between the metal precursor and the substrate.

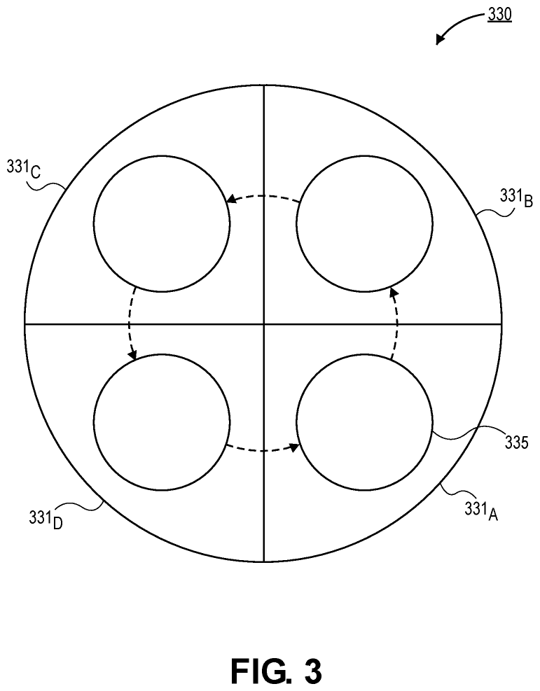

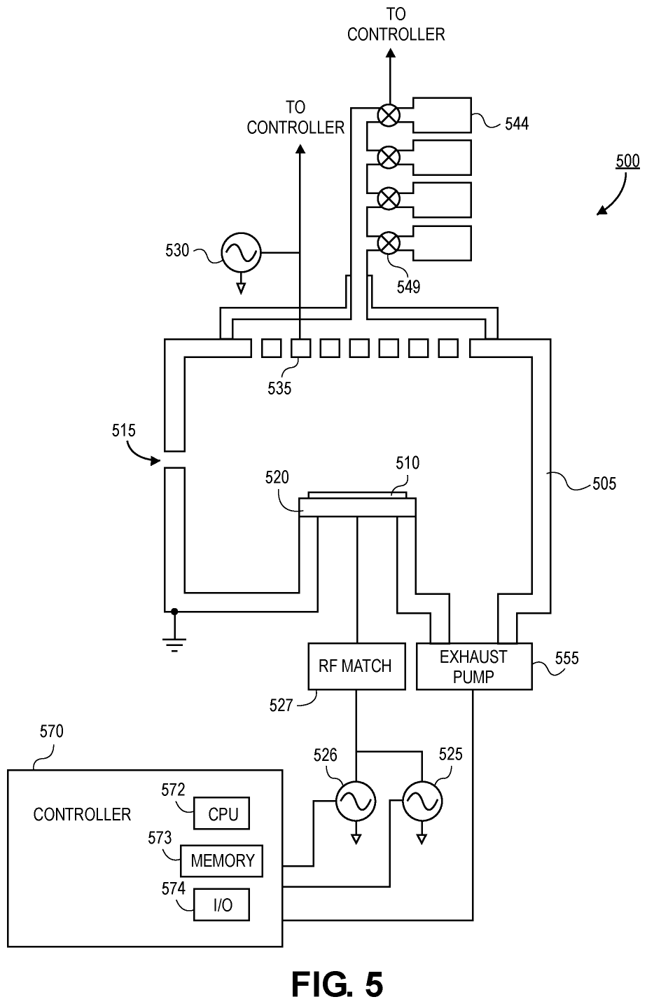

In an embodiment, the vacuum chamber utilized in process 100 may be any suitable chamber capable of providing a sub-atmospheric pressure. In an embodiment, the vacuum chamber may include temperature control features for controlling chamber wall temperatures and/or for controlling a temperature of the substrate. In an embodiment, the vacuum chamber may also include features for providing a plasma within the chamber. Detailed descriptions of suitable vacuum chambers are provided below with respect to FIG. 3 or FIG. 5.

It is to be appreciated that particular processing parameters during the execution of process 100 may be chosen in order to enhance one or more properties of the metal oxo film. Generally, process conditions may include a showerhead temperature that is between approximately −20° C. and approximately 175° C. A pedestal temperature may also be between approximately −20° C. and approximately 175° C. In an embodiment, a pressure in the chamber may be less than approximately 10 T. In other embodiments, the pressure may be between approximately 0.01 T and approximately 10 T. A spacing between the substrate and the showerhead may be between approximately 100 mil and approximately 4,000 mil. With respect to the gas flows, the precursor gas may have a flow rate between approximately 0.1 slm and approximately 5 slm. The flowrate of the precursor may include a carrier gas (e.g., Ar or N₂). The flowrate of the oxidant (e.g., H₂O) may be between approximately 50 mgm and approximately 500 mgm. Carrier gasses (e.g., Ar or N₂) may be used to carrier the oxidant into the chamber. The carrier gasses may have flow rates between approximately 0.01 slm and approximately 5 slm.

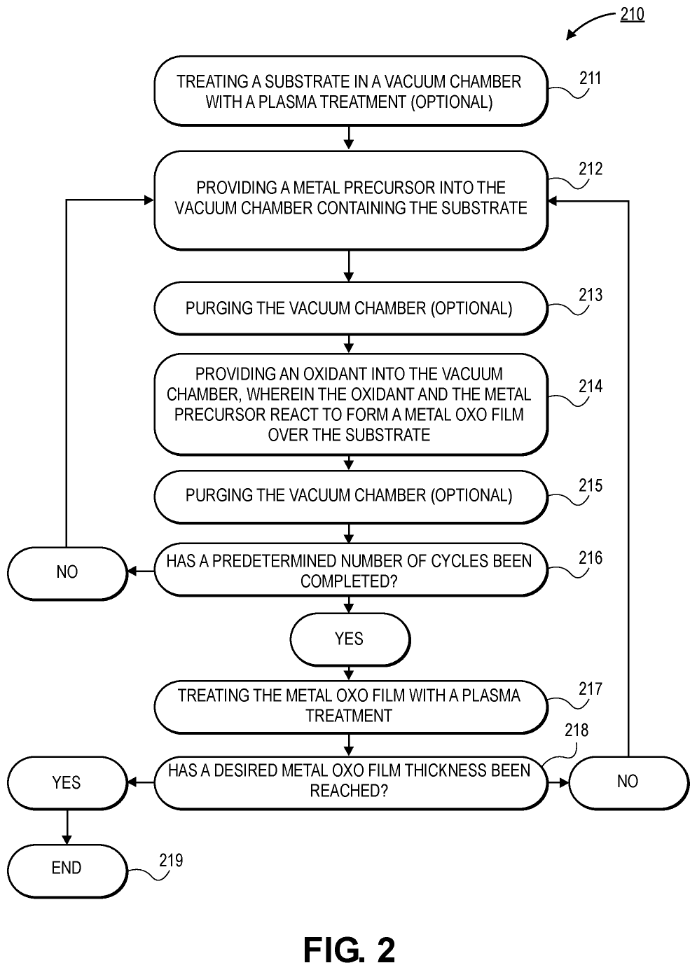

Referring now to FIG. 2, a flow diagram of a process 210 is shown, in accordance with an additional embodiment. In an embodiment, process 210 may begin with operation 211, which comprises treating a substrate in a vacuum chamber with a plasma treatment. Operation 211 may be used to prepare the surface of the substrate in order to provide improved adhesion with the metal oxo film. In some embodiments, the initial plasma treatment operation 211 is optional. That is, process 210 may begin with operation 212 in some embodiments.

In an embodiment, operation 212 may comprise providing a metal precursor into the vacuum chamber containing the substrate. In an embodiment, the metal precursor may be substantially similar to the metal precursor described above in process 100, and will not be repeated here.

In an embodiment, process 210 may continue with operation 213, which comprises purging the vacuum chamber. In an embodiment, the purging operation is optional. That is, process 210 may continue directly to operation 214 after operation 212 in some embodiments. The purge of the chamber may comprise flowing an inert gas such as Ar, N₂, or He into the chamber.

In an embodiment, process 210 may continue with operation 214, which comprises providing an oxidant into the vacuum chamber. In an embodiment, the oxidant reacts with the metal precursor to form a metal oxo film over the substrate. In an embodiment, the oxidant in operation 214 may be substantially similar to the oxidant in operation 103 and will not be repeated here.

In an embodiment, process 210 may continue with operation 215, which comprises purging the vacuum chamber. In an embodiment, the purging operation is optional. That is, process 210 may continue directly to operation 216 after operation 214 in some embodiments. The purge of the chamber may comprise flowing an inert gas such as Ar, N₂, or He into the chamber.

In an embodiment, process 210 may continue with operation 216, which comprises determining if a predetermined number of deposition cycles have been completed. Each deposition cycle may refer to an iteration of operations 212-215. When the predetermined number of deposition cycles have not been completed, then the process 210 loops back to operation 212 to start a new deposition cycle. When the predetermined number of deposition cycles have been completed, then the process 210 continues to operation 217.

In an embodiment, operation 217 comprises treating the metal oxo film with a plasma treatment. In an embodiment, the plasma treatment may include a plasma generated from one or more inert gasses, such as Ar, N₂, He, etc. In an embodiment, the inert gas or gasses may also be mixed with one or more oxygen containing gasses, such as O₂, CO₂, CO, NO, NO₂, H₂O, etc. In an embodiment, the vacuum chamber may be purged after to operation 217. The purge may comprise a pulse of an inert gas such as Ar, N₂, He, etc.

After operation 217, process 210 may continue with operation 218. Operation 218 may comprise determining if a desired metal oxo film thickness has been reached. If the desired thickness has not been reached, then the processing may continue by looping back to operation 212. If the desired thickness has been reached, then the processing may continue to operation 219, where the process 210 is ended. In such a case, the final plasma treatment of operation 217 may be considered a “post treatment”. In some embodiments, the process 210 may end before a post treatment is implemented.

In some embodiments, the plasma treatment operation 217 is implemented regularly after a predetermined number of deposition cycles. For example, the plasma treatment operation 217 may be implemented every ten deposition cycles. In other embodiments, the predetermined number of deposition cycles may vary between plasma treatment operations 217. For example, a first plasma treatment operation 217 may be implemented after ten deposition cycles, and a second plasma treatment operation 217 may be implemented after twenty more deposition cycles.

Similar to the process 100, process 210 may be implemented as a thermal process or a plasma enhanced process. For example, a plasma may be ignited during one or more of the operations 212-215. Additionally, while the deposition cycle (i.e., operations 212-215) start with flowing a metal precursor, it is to be appreciated that the deposition cycle may optionally start with flowing the oxidant.

In an embodiment, the vacuum chamber utilized in process 210 may be any suitable chamber capable of providing a sub-atmospheric pressure. In an embodiment, the vacuum chamber may include temperature control features for controlling chamber wall temperatures and/or for controlling a temperature of the substrate. In an embodiment, the vacuum chamber may also include features for providing a plasma within the chamber. Detailed descriptions of suitable vacuum chambers are provided below with respect to FIG. 3 or FIG. 5.

It is to be appreciated that particular processing parameters during the execution of process 210 may be chosen in order to enhance one or more properties of the metal oxo film. Generally, process conditions may include a showerhead temperature that is between approximately −20° C. and approximately 175° C. A pedestal temperature may also be between approximately −20° C. and approximately 175° C. In an embodiment, a pressure in the chamber may be less than approximately 10 T. In other embodiments, the pressure may be between approximately 0.01 T and approximately 10 T. A spacing between the substrate and the showerhead may be between approximately 100 mil and approximately 4,000 mil. With respect to the gas flows, the precursor gas may have a flow rate between approximately 0.1 slm and approximately 5 slm. The flowrate of the precursor may include a carrier gas (e.g., Ar or N₂). The flowrate of the oxidant (e.g., H₂O) may be between approximately 50 mgm and approximately 500 mgm. Carrier gasses (e.g., Ar or N₂) may be used to carrier the oxidant into the chamber. The carrier gasses may have flow rates between approximately 0.01 slm and approximately 5 slm.

In yet another embodiment, a deposition process that utilizes multiple metal precursors is used. A first metal precursor may have a general formula of MRₓL_{4-X}. The first metal precursor may be substantially similar to the metal precursors described above. A second metal precursor may have a general formula of ML₄, where L is an alkylamine. That is, the second metal precursor may not include an R group comprising carbon. As such, modulation between the first metal precursor and the second metal precursor may be used to modulate the amount of carbon in the film.

In an embodiment, the deposition process may utilize a loop comprising a first cycle and a second cycle. The first cycle comprising flowing the first metal precursor followed by flowing an oxidant. The first cycle may be repeated any number of times. The loop may then continue with a second cycle comprising flowing the second metal precursor followed by flowing an oxidant. The second cycle may also be repeated any number of times. In an embodiment, iterations of the loop may be repeated any number of times to provide a film with a desired thickness. It is to be appreciated that the deposition loop may begin with iterations of the first cycle or with iterations of the second cycle.

Such a deposition process provides for flexibility in the composition of the film. For example, using a loop that starts with the second cycle (or includes a larger number of iterations of the second cycle) can be used to form a film that has a lower carbon concentration at the interface with the underlying substrate. This may provide improved adhesion. Also, by gradually changing the number of iterations of the first cycle and the second cycle in each loop, a composition gradient can be achieved in the film.

Referring now to FIG. 3, a plan view illustration of a chamber 330 is shown, in accordance with an embodiment. In an embodiment, the chamber 330 may be controlled in accordance with instructions stored in the memory to execute one or more metal oxo deposition processes. For example, one or more processes such as processes 100 and 210 described above may be executed in the vacuum chamber 330. In an embodiment, the chamber 330 may comprise a plurality of regions 331_{A-D}. While four regions 331 are shown, it is to be appreciated that the chamber 330 may comprise two or more regions 331. In an embodiment, substrates 335 are provided in the regions 331. The substrates 335 are rotated through the different regions 331, as indicated by the arrows.

In an embodiment, each region 331 of the chamber 330 is responsible for executing one of the processing operations in the deposition cycle used to form the metal oxo photoresist. For example, in region 331_{A} a metal precursor may be flown into the chamber, in region 331_{B} a purge may be provided, in region 331_{C} an oxidant may be flown into the chamber, and in region 331_{D} a purge may be provided. In some embodiments, the boundary between the regions 331 may comprise features for purging. In such an embodiment, regions 331_{A} and 331_{C} may provide the metal precursor and regions 331_{B} and 331_{D} may provide the oxidant. As such, two deposition cycles may occur on the substrate 335 with each full rotation through the chamber 330.

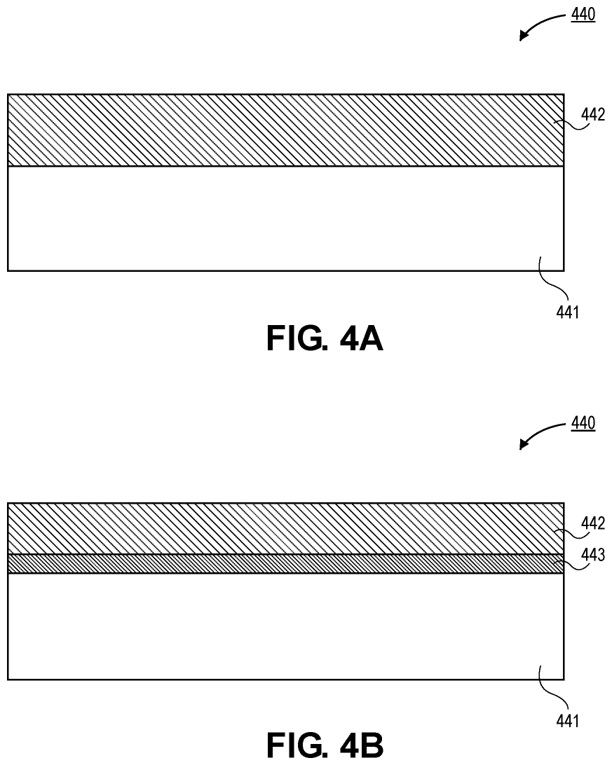

Referring now to FIG. 4A, a cross-sectional illustration of a wafer 440 is shown in accordance with an embodiment. The wafer 440 comprises a base substrate 441 and a metal oxo photoresist 442 over the base substrate 441. The base substrate 441 may comprise silicon or other materials used in semiconductor manufacturing. In an embodiment, the metal oxo photoresist 442 may be deposited over the base substrate 441 using processes such as those described above. In an embodiment, the metal oxo photoresist 442 has a uniform composition and a uniform thickness. Such an embodiment may be provided when each of the deposition cycles are substantially uniform.

However, it is to be appreciated that non-uniform material compositions through a thickness of the metal oxo photoresist 442 are also possible. An example of such an embodiment is shown in FIG. 4B. As shown, an interface layer 443 is provided between the metal oxo photoresist 442 and the base substrate 441. The interface layer 443 may be a metal oxo material that is tuned to have improved adhesion strength compared to that of the metal oxo photoresist 442. In an embodiment, the interface layer 443 may have a thickness of approximately several nanometers to hundreds of nanometers. The interface layer 443 may be formed with a deposition cycle (or cycles) that are different than the deposition cycles used to form the remainder of the metal oxo photoresist 442. For example, different metal precursors and/or different oxidants may be used to form the interface layer 443 and the metal oxo photoresist 442.

Providing metal oxo photoresist films using vapor phase processes such as described in the embodiments above provides significant advantages over wet chemistry methods. One such advantage is the elimination of wet byproducts. With a vapor phase process, liquid waste is eliminated and byproduct removal is simplified. Additionally, vapor phase processes provide a more uniform photoresist layer. Uniformity in this sense may refer to thickness uniformity across the wafer and/or uniformity of the distribution of metal components of the metal oxo film. Particularly, ALD and PE-ALD processes have been shown to provide excellent thickness uniformity and constituent uniformity.

Additionally, the use of vapor phase processes provides the ability to fine-tune the percentage of metal in the photoresist and the composition of the metal in the photoresist. The percentage of the metal may be modified by increasing/decreasing the flow rate of the metal precursor into the vacuum chamber and/or by modifying the pulse lengths of the metal precursor/oxidant. The use of a vapor phase process also allows for the inclusion of multiple different metals into the metal oxo film. For example, a single pulse flowing two different metal precursors may be used, or alternating pulses of two different metal precursors may be used.

Furthermore, it has been shown that metal oxo photoresists that are formed using vapor phase processes are more resistant to thickness reduction after exposure. It is believed, without being tied to a particular mechanism, that the resistance to thickness reduction is attributable, at least in part, to the reduction of carbon loss upon exposure.

FIG. 5 is a schematic of a vacuum chamber configured to perform a vapor phase deposition of a metal oxo photoresist, in accordance with an embodiment of the present disclosure. Vacuum chamber 500 includes a grounded chamber 505. A substrate 510 is loaded through an opening 515 and clamped to a temperature controlled chuck 520.

Process gases, are supplied from gas sources 544 through respective mass flow controllers 549 to the interior of the chamber 505. In certain embodiments, a gas distribution plate 535 provides for distribution of process gases, such as a metal precursor, an oxidant, and an inert gas. Chamber 505 is evacuated via an exhaust pump 555.

When RF power is applied during processing of a substrate 510, a plasma is formed in chamber processing region over substrate 510. Bias power RF generator 525 is coupled to the temperature controlled chuck 520. Bias power RF generator 525 provides bias power, if desired, to energize the plasma. Bias power RF generator 525 may have a low frequency between about 2 MHz to 60 MHz for example, and in a particular embodiment, is in the 13.56 MHz band. In certain embodiments, the vacuum chamber 500 includes a third bias power RF generator 526 at a frequency at about the 2 MHz band which is connected to the same RF match 527 as bias power RF generator 525. Source power RF generator 530 is coupled through a match (not depicted) to a plasma generating element (e.g., gas distribution plate 535) to provide a source power to energize the plasma. Source RF generator 530 may have a frequency between 100 and 180 MHz, for example, and in a particular embodiment, is in the 162 MHz band. Because substrate diameters have progressed over time, from 150 mm, 200 mm, 300 mm, etc., it is common in the art to normalize the source and bias power of a plasma etch system to the substrate area.

The vacuum chamber 500 is controlled by controller 570. The controller 570 may comprise a CPU 572, a memory 573, and an I/O interface 574. The CPU 572 may execute processing operations within the vacuum chamber 500 in accordance with instructions stored in the memory 573. For example, one or more processes such as processes 100 and 210 described above may be executed in the vacuum chamber by the controller 570.

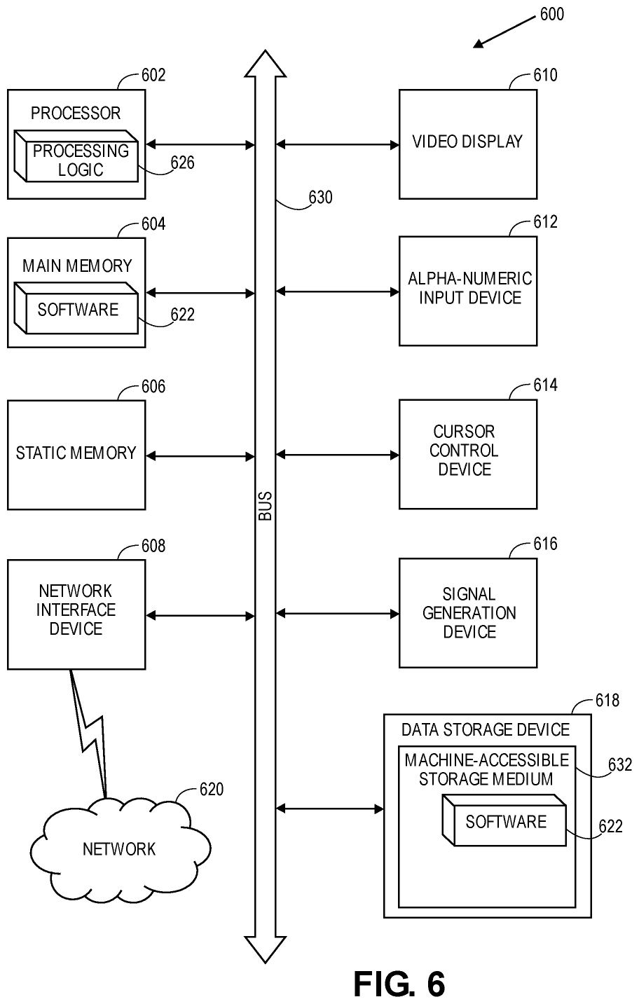

FIG. 6 illustrates a diagrammatic representation of a machine in the exemplary form of a computer system 600 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 600 includes a processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), MRAM, etc.), and a secondary memory 618 (e.g., a data storage device), which communicate with each other via a bus 630.

Processor 602 represents one or more general-purpose processing devices such as a microprocessor, central processing unit, or the like. More particularly, the processor 602 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 602 may also be one or more special-purpose processing devices such as an application specific integrated circuit (ASIC), a field programmable gate array (FPGA), a digital signal processor (DSP), network processor, or the like. Processor 602 is configured to execute the processing logic 626 for performing the operations described herein.

The computer system 600 may further include a network interface device 608. The computer system 600 also may include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium (or more specifically a computer-readable storage medium) 632 on which is stored one or more sets of instructions (e.g., software 622) embodying any one or more of the methodologies or functions described herein. The software 622 may also reside, completely or at least partially, within the main memory 604 and/or within the processor 602 during execution thereof by the computer system 600, the main memory 604 and the processor 602 also constituting machine-readable storage media. The software 622 may further be transmitted or received over a network 620 via the network interface device 608.

While the machine-accessible storage medium 632 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, and optical and magnetic media.

In accordance with an embodiment of the present disclosure, a machine-accessible storage medium has instructions stored thereon which cause a data processing system to perform a method of depositing a metal oxo photoresist on a substrate. The method includes vaporizing a metal precursor into a vacuum chamber and vaporizing an oxidant into the vacuum chamber. The metal precursor and the oxidant may be sequentially provided into the vacuum chamber. The reaction between the metal precursor and the oxidant result in the formation of the metal oxo photoresist on the substrate. The metal oxo photoresist may be treated with a plasma treatment in some embodiments.

Thus, methods for forming a metal oxo photoresist using vapor phase processes have been disclosed.

What is claimed is:

1. A method of forming a metal-oxo photoresist on a substrate, comprising:
repeating a deposition cycle, wherein each iteration of the deposition cycle comprises:
a) flowing a metal precursor into a chamber comprising the substrate; and
b) flowing an oxidant into the chamber, wherein the oxidant and the metal precursor react to form the metal-oxo photoresist.

2. The method of claim 1, wherein in at least one iteration of the deposition cycle, the chamber is purged between operation a) and operation b).

3. The method of claim 1, wherein in at least one iteration of the deposition cycle, the chamber is purged after operation b) and before operation a) of a successive deposition cycle.

4. The method of claim 1, wherein the oxidant comprises two or more constituents, and/or wherein the metal precursor comprises two or more constituents.

5. The method of claim 1, wherein a first deposition cycle comprises a first metal precursor, and wherein a second deposition cycle comprises a second metal precursor that is different than the first metal precursor.

6. The method of claim 1, wherein a first deposition cycle comprises a first oxidant, and wherein a second deposition cycle comprises a second oxidant that is different than the first oxidant.

7. The method of claim 1, wherein operation b) is executed before operation a).

8. The method of claim 1, further comprising:
igniting a plasma during operation a) in one or more iterations of the deposition cycle and/or igniting a plasma during operation b) in one or more iterations of the deposition cycle.

9. The method of claim 1, wherein operation a) is implemented in a first region of the chamber and operation b) is implemented in a second region of the chamber, and wherein the substrate is rotated between the first region of the chamber and the second region of the chamber.

10. The method of claim 1, wherein the metal precursor comprises a general formula of MR_{X}L_{Y}, where X=0-4 and Y=4-X, and wherein M is a metal, R is a linear alkyl, a branched alkyl, or a cyclic alkyl, and L is a alkyl amino, Cl, Br, CN, CNO, SCN, N₃, or SeCN.

11. The method of claim 10, wherein M is Sn.

12. The method of claim 1, wherein the oxidant comprises one or more of water, O₂, ethylene glycol, alcohols, peroxides, and acids.

13. The method of claim 1, wherein the substrate is rotated between different sections of the chamber to implement operation a) and operation b).

14. A method of forming a metal-oxo photoresist on a substrate, comprising:
repeating a deposition cycle, wherein each iteration of the deposition cycle comprises:
a) flowing a metal precursor into a chamber comprising the substrate; and
b) flowing an oxidant into the chamber, wherein the oxidant and the metal precursor react to form the metal-oxo photoresist; and
treating the metal-oxo photoresist with a plasma treatment after a first number of iterations of the deposition cycle.

15. The method of claim 14, further comprising:
treating the substrate with an initial plasma treatment prior to initiating a first iteration of the deposition cycle.

16. The method of claim 14, further comprising:
restarting iterations of the deposition cycle after the plasma treatment.

17. The method of claim 16, further comprising:
treating the metal-oxo photoresist with a second plasma treatment after a second number of iterations of the deposition cycle.

18. The method of claim 17, wherein the first number of iterations of the deposition cycle is different than the second number of iterations of the deposition cycle.

19. A method of forming a metal oxo photoresist on a substrate, comprising:
repeating a deposition cycle, wherein each iteration of the deposition cycle comprises:
a) flowing a metal precursor into a chamber comprising the substrate, wherein the metal precursor comprises a general formula of MR_{X}L_{Y}, where X=0-4 and Y=4-X, and wherein M is a metal, R is a linear alkyl, a branched alkyl, or a cyclic alkyl, and L is a alkyl amino, Cl, Br, CN, CNO, SCN, N₃, or SeCN;
b) purging the chamber;
c) flowing an oxidant into the chamber, wherein the oxidant and the metal precursor react to form the metal oxo photoresist, wherein the oxidant comprises one or more of water, O₂, ethylene glycol, alcohols, peroxides, and acids; and
d) purging the chamber.

20. The method of claim 19, further comprising:
igniting a plasma during operation a) and/or operation c) in one or more iterations of the deposition cycle.
